(19) United States
(12) Patent Application Publication
(10) Pub. No.: US 2013/0286558 A1
(43) Pub. Date: Oct. 31, 2013

(54) PORTABLE ELECTRONIC DEVICE AND PROTECTOR

(71) Applicant: CAI-JIN YUAN, Shenzhen City (CN)

(72) Inventor: CAI-JIN YUAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/544,146

(22) Filed: Jul. 9, 2012

(30) Foreign Application Priority Data
Apr. 25, 2012 (CN) 201210123012.4

(51) Int. Cl. H05K 7/00

(52) U.S. Cl. 361/679.01

(57) ABSTRACT

A portable electronic device includes a main body and a protector. The main body includes a first surface and a second surface opposite to the first surface, and two sidewalls opposite to each other. Each sidewall defines a slide groove therein. The protector includes a sheet having two opposite sidewalls, and two slide tabs oppositely arranged on the two opposite sidewalls of the sheet. Each slide tab forms a slide post thereon. The slide posts engages in the slide grooves to allow the protector sliding along the slide grooves and pivoting around the slide posts to respectively cover the first surface or the second surface of the main body.

### BACKGROUND

1. Technical Field

The present disclosure relates to a portable electronic device and a protector of the portable electronic device.

2. Description of Related Art

Most of portable electronic devices, such as mobile-phones and personal digital assistants, commonly have large liquid crystal panels. However, the liquid crystal panels have poor shock resistances. When dropped, the liquid crystal panels are prone to be damaged. Additionally, the liquid crystal panels are also prone to scratch while being carried. Accordingly, pockets or bags are designed to cover the devices for protecting the panels from scratch or damage. However, the use of the pockets or bags may be inconvenient.

Therefore, there is room for improvement within the art.

### BRIEF DESCRIPTION OF THE DRAWINGS

Many aspects of the disclosure can be better understood with reference to the following figures. The components in the figures are not necessarily drawn to scale, the emphasis instead being placed upon clearly illustrating the principles of the disclosure. Moreover, in the drawings, like reference numerals designate corresponding parts throughout the several views.

FIG. 1 is an exploded view of an exemplary embodiment of a portable electronic device including a protector and a main body.

FIG. 2 is a schematic view of the protector shown in FIG. 1 located on a first surface of the main body.

FIG. 3 is a schematic view of the protector sliding along the main body.

FIG. 4 is a schematic view of the protector located on a second surface of the main body.

### DETAILED DESCRIPTION

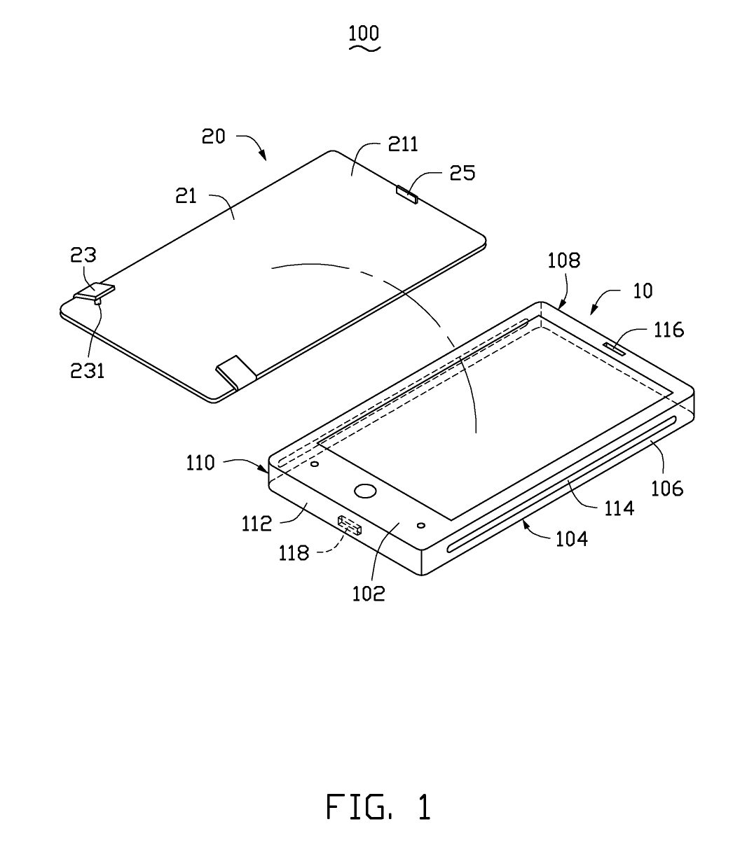

FIG. 1 illustrates a portable electronic device 100 according to an exemplary embodiment. The portable electronic device 100 includes a main body 10 and a protector 20.

The main body 10 may be a mobile-phone, or a personal digital assistant. The main body 10 defines the known displaying module, power supply module, and key assembly. The main body 10 includes a first surface 102, a second (under) surface 104 opposite to the first surface 102, and four sidewalls 106, 108, 110, and 112 that are all adjacent to and framing the first and second surfaces 102 and 104. The sidewalls 106 and 110 are arranged opposite to each other. The sidewalls 108 and 112 are arranged opposite to each other.

The main body 10 defines two slide grooves 114, a first notch 116, and a second notch 118. The two slide grooves 114 are arranged in parallel and respectively defined in the sidewalls 106 and 110. The first notch 116 is defined in the first surface 102 and adjacent to the sidewall 108. The second notch 118 is defined in the second surface 104 and adjacent to the sidewall 112.

The protector 20 includes a sheet 21, two slide tabs 23, and a fastening portion 25. The sheet 21 may be flexible and the slide tabs 23 may be bent towards or away from bottom surface 211. The slide tabs 23 are arranged on opposite sidewalls of the sheet 21, and biased towards bending towards the bottom surface 211. A slide post 231 protrudes from each slide tab 23. Each slide post 231 engages in one of the slide grooves 114 with the slide post 231 latching with the peripheral wall of the slide groove 114 when the slide tabs 23 are perpendicular to the bottom surface 211. As such, the protector 20 can move along the slide grooves 114, and the slide tabs 23 cannot slide out of the slide grooves 114.

The fastening portion 25 is positioned at the end of the sheet 21 away from the two slide tabs 23, and also protrudes from the surface 211 of the sheet 21. In the embodiment, the fastening portion 25 is a flexible latching protrusion and is configured for engaging or clasping in the first notch 116 or the second notch 118 to further secure the protector 20 to the main body 10.

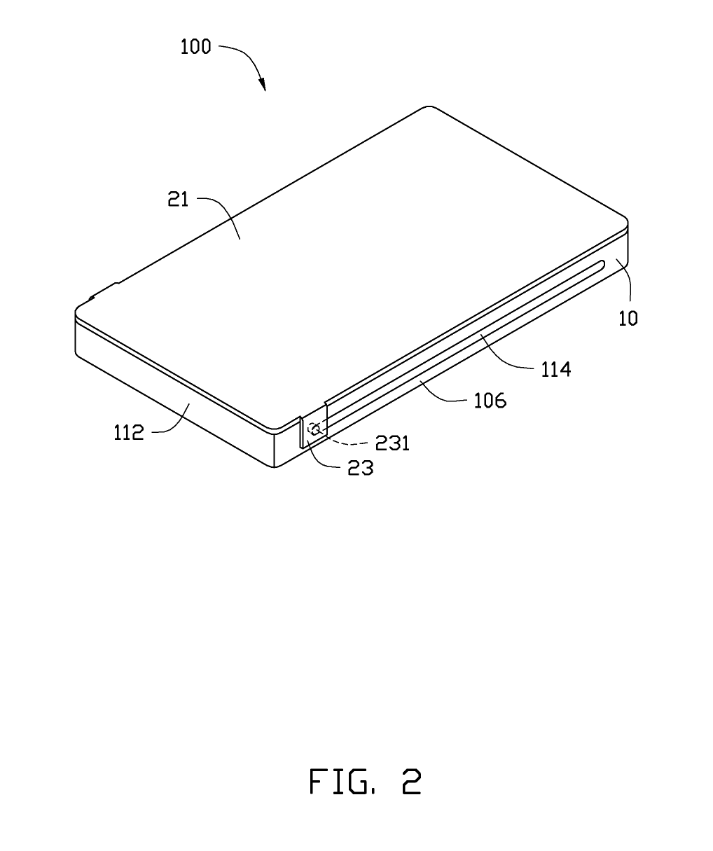

Also referring to FIG. 2, when in assembly of the protector 20 to the main body 10, the two slide posts 231 of the slide tabs 23 are inserted into the slide grooves 114, which allows the slide posts 231 to latch with the peripheral wall of the slide grooves 114. As such, the protector 20 is slidably mounted on the main body 10.

When the main body 10 is not in use, the slide tabs 23 of the protector 20 slide to one of the ends of the slide grooves 114, then the protector 20 is pressed to make the fastening portion 25 latch in the first notch 116. As such, the protector 20 is mounted on the main body 10 directly covering the first surface 102 to protect the panel of the main body 10.

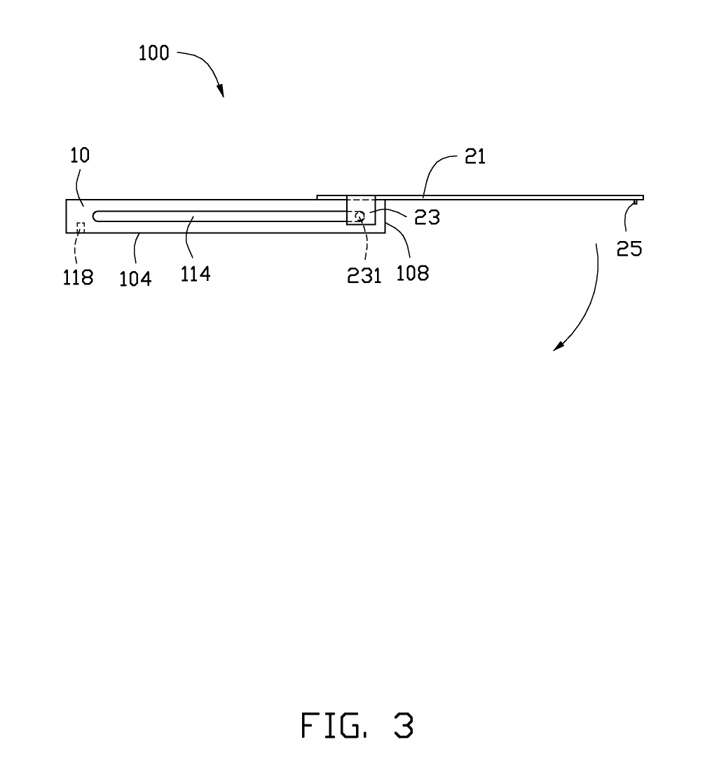

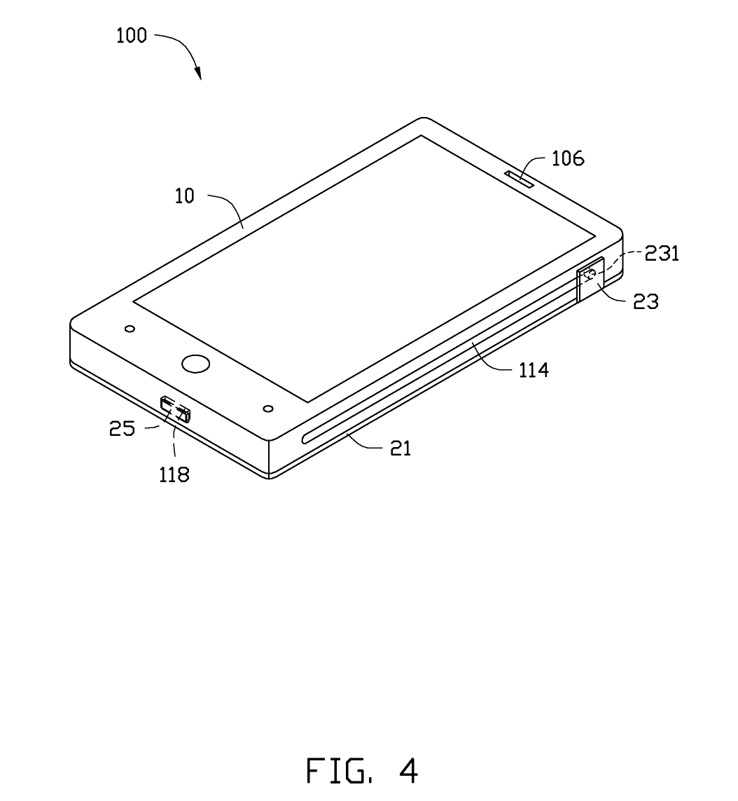

Referring to FIGS. 3 and 4, when the main body 10 is in use, the protector 20 is pressed at the region having the fastening portion 25 to compress the fastening portion 25. Then the pressing is released and the fastening portion 25 pops out of the first notch 116. Alternatively, the fastening portion 25 may be directly pulled out of the first notch 116 by pulling the sheet 21 upwards. Then the slide tabs 23 of the protector 20 slide along the slide grooves 114 to arrive at the other ends of the slide grooves 114 adjacent to the sidewall 108. At this time, the protector 20 is pivoted around the slide posts 231 to come to the second surface 104 of the main body 10. Then the protector 20 is pressed to make the fastening portion 25 latch in the second notch 118. As such, the protector 20 is mounted on the main body 10 and directly covers the second surface 104. Then users can use the main body 10.

The protector 20 may be colored to present an atheistic and attractive appearance.

The protector 20 of the portable electronic device 100 can easily slide on the main body 10 and pivot to the first surface 102 to protect the panel of the main body 10 or to the second surface 104 for users to use the main body 10. Compared to the pockets and bags, the use of the protector 20 of the exemplary embodiment is very convenient.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A protector of a portable electronic device, comprising:
a sheet comprising two opposite sidewalls; and
two slide tabs, each slide tab arranged on one of the two opposite sidewalls of the sheet, each slide tab forming a slide post thereon.

2. The protector as claimed in claim 1, further comprising a fastening portion positioned at the end of the sheet spaced from the two slide tabs.

3. The protector as claimed in claim 2, wherein the fastening portion is a flexible latching protrusion.

4. The protector as claimed in claim 3, wherein the slide tabs bend towards or away from bottom surface of the sheet, the fastening portion is protruded from the bottom surface of the sheet.

5. The protector as claimed in claim 1, wherein the sheet is flexible.

6. A portable electronic device, comprising:
a main body, the main body comprising:
a first surface and a second surface opposite to the first surface; and
two sidewalls opposite to each other, each sidewall defining a slide groove therein;
and a protector, the protector comprising:
a sheet comprising two opposite sidewalls; and
two slide tabs, each slide tab arranged on one of the two opposite sidewalls of the sheet, each slide tab forming a slide post thereon, the slide posts engaging in the slide grooves to allow the protector sliding along the slide grooves and pivoting around the slide posts to respectively cover the first surface or the second surface of the main body.

7. The portable electronic device as claimed in claim 6, wherein the two slide grooves are arranged in parallel in the two sidewalls of the main body, each slide groove defines a peripheral wall.

8. The portable electronic device as claimed in claim 7, wherein each slide post engages in a slide groove with the slide post latching with the peripheral wall of the slide groove.

9. The portable electronic device as claimed in claim 6, wherein the protector further comprises a fastening portion positioned at the end of the sheet spaced from the two slide tabs, the main body further defines a first notch in the first surface and a second notch in the second surface, the fastening portion engages in the first notch or engages in the second notch to secure the protector on the main body.

10. The portable electronic device as claimed in claim 9, wherein when the main body is not in use, the fastening portion is latched in the first notch to make the protector mount on the main body and cover the first surface of the main body.

11. The portable electronic device as claimed in claim 10, wherein when the main body is in use, the protector is pivoted around the slide posts to cover the second surface of the main body, then the fastening portion is latched in the second notch to make the protector mount on the main body.

12. The portable electronic device as claimed in claim 9, wherein the fastening portion is a flexible latching protrusion.

13. The portable electronic device as claimed in claim 9, wherein the slide tabs bend towards or away from bottom surface of the sheet, the fastening portion is protruded from the bottom surface of the sheet.

14. The portable electronic device as claimed in claim 6, wherein the sheet is flexible.
